(19) United States
(12) Patent Application Publication
(10) Pub. No.: US 2015/0243355 A1
(43) Pub. Date: Aug. 27, 2015

(54) VARIABLE RESISTANCE MEMORY DEVICE AND RELATED PROGRAMMING METHOD DESIGNED TO REDUCE PEAK CURRENT

(71) Applicant: SAMSUNG ELECTRONICS CO., LTD., SUWON-SI (KR)

(72) Inventors: YONGKYU LEE, SUWON-SI (KR); YEONGTAEK LEE, SEOUL (KR)

(21) Appl. No.: 14/532,105

(22) Filed: Nov. 4, 2014

(30) Foreign Application Priority Data
Feb. 21, 2014 (KR) 0-2014-0020612

(51) Int. Cl. G11C 13/00

(52) U.S. Cl. CPC G11C 13/0069

(57) ABSTRACT

A method is provided for programming a nonvolatile memory device comprising a variable resistance memory cell connected to a bitline and a wordline. The method comprises precharging the bitline to a first bias voltage, precharging the wordline to a second bias voltage, wherein a voltage difference between the first bias voltage and the second bias voltage is less than a threshold voltage of the memory cell, and applying a first write voltage to the bitline and a second write voltage to the wordline in response to a select signal, wherein a voltage difference between the first write voltage and the second write voltage is greater than the threshold voltage.

### CROSS-REFERENCE TO RELATED APPLICATIONS

This application claims priority under 35 U.S.C. §119 of Korean Patent Application No. 10-2014-0020612, filed on Feb. 21, 2014, the entire contents of which are hereby incorporated by reference.

### BACKGROUND OF THE INVENTION

The inventive concept relates generally to nonvolatile memory devices and related methods of programming. More particularly, the inventive concept relates to variable resistance memory devices and related methods of programming.

There is a continuing demand for nonvolatile semiconductor memory devices having high integration density and high storage capacity. Accordingly, researchers continue to seek ways to improve these and other aspects of nonvolatile semiconductor memory devices.

Examples of nonvolatile semiconductor memory devices include ferroelectric RAM (FRAM), magnetic RAM (MRAM), and various forms of variable resistance memories such as phase-change RAM (PRAM), to name but a few. Resistive RAM (RRAM), which is a type of variable resistance memory, may be designed to have relatively high speed, high capacity, low power, etc. Moreover, ongoing research efforts are aimed at improving these characteristics.

A variable resistance material layer of an RRAM exhibits a reversible resistance change based on a polarity and amplitude of an applied pulse. A colossal magnetro-resistive (CMR) material layer with a Perovskite structure or a metal oxide layer in which a conductive filament is created or removed by an electric pulse has been proposed as a variable resistance material layer.

### SUMMARY OF THE INVENTION

In one embodiment of the inventive concept, a method is provided for programming a nonvolatile memory device comprising a variable resistance memory cell connected to a bitline and a wordline. The method comprises precharging the bitline to a first bias voltage, precharging the wordline to a second bias voltage, wherein a voltage difference between the first bias voltage and the second bias voltage is less than a threshold voltage of the memory cell, and applying a first write voltage to the bitline and a second write voltage to the wordline in response to a select signal, wherein a voltage difference between the first write voltage and the second write voltage is greater than the threshold voltage.

In another embodiment of the inventive concept, a nonvolatile memory device comprises a memory cell array comprising a memory cell in which data is stored by changing the memory cell's resistance value, an input/output driver connected to the memory cell array through a first switch group connected to a plurality of wordlines and a second switch group connected to a plurality of bitlines, and control logic configured to control the input/output driver such that, in a program operation, a selected wordline and a selected bitline that are connected to a selected memory cell are precharged to a predetermined bias voltage before switches in the first and second switch groups are activated.

In another embodiment of the inventive concept, a method is provided for programming a nonvolatile memory device comprising a variable resistance memory cell connected to a global wordline, a global bitline, a local wordline, and a local bitline. The method comprises precharging the global wordline and the global bitline to a first bias voltage that is lower than a threshold voltage of the memory cell, precharging the local wordline and the local bitline to a second bias voltage that is lower than the first bias voltage, turning on select transistors connected to the memory cell, and applying a write voltage to the memory cell via the local wordline, the local bitline, and the select transistors.

These and other embodiments of the inventive concept can potentially reduce peak current in a set program operation of a nonvolatile memory device, which can improve the endurance of the nonvolatile memory device.

### BRIEF DESCRIPTION OF THE DRAWINGS

The drawings illustrate selected embodiments of the inventive concept. In the drawings, like reference numbers indicate like features.

FIG. 1 is a block diagram illustrating a nonvolatile memory device according to an embodiment of the inventive concept.

FIG. 2 is a drawing illustrating a structure of a variable resistance memory device.

FIG. 3 illustrates a variable resistance memory cell without a select device.

FIG. 4 illustrates a variable resistance memory cell with a select device.

FIG. 5 is a circuit diagram illustrating a memory cell of FIG. 2 connected between a bitline and a wordline.

FIG. 6 is a graph illustrating a current flowing through a memory cell MC and a voltage provided to switches connected to memory cell MC in a set state program operation.

FIG. 7 is a graph illustrating a hysteresis characteristic of a variable resistance memory cell according to an embodiment of the inventive concept.

FIG. 8 is a graph illustrating a hysteresis characteristic of a variable resistance device on a Log scale.

FIG. 9 is a timing diagram illustrating a method of programming a nonvolatile memory device according to an embodiment of the inventive concept.

FIG. 10 is a flowchart illustrating a method of programming a nonvolatile memory device according to an embodiment of the inventive concept.

FIG. 11 is a flowchart illustrating a method of programming a nonvolatile memory device according to an embodiment of the inventive concept.

FIG. 12 is a circuit diagram illustrating another example of the memory cell of FIG. 2 connected between a bitline and a wordline.

FIG. 13 is a block diagram illustrating a portable electronic system comprising a resistive memory device according to an embodiment of the inventive concept.

FIG. 14 is a block diagram illustrating a memory card comprising a nonvolatile memory device according to an embodiment of the inventive concept.

FIG. 15 is a drawing illustrating various systems in which a memory card of FIG. 14 is used.

### DETAILED DESCRIPTION

Embodiments of the inventive concept are described below with reference to the accompanying drawings. These embodiments are presented as teaching examples and should not be construed to limit the scope of the inventive concept.

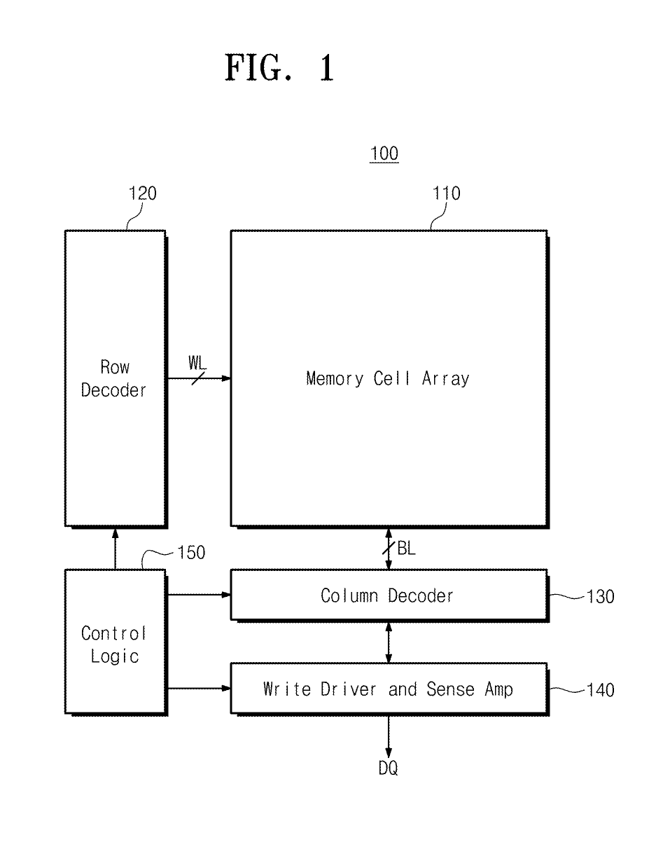

FIG. 1 is a block diagram illustrating a nonvolatile memory device 100 according to an embodiment of the inventive concept.

Referring to FIG. 1, nonvolatile memory device 100 comprises a memory cell array 110, a row decoder 120, a column decoder 130, a write driver and sense amplifier (WD/SA) 140, and control logic 150. Memory cells of memory cell array 110 can be programmed to different states using a “set” program operation or a “reset” program operation, examples of which will be presented below.

Where a set program operation is performed on a selected memory cell of memory cell array 110, nonvolatile memory device 100 precharges a voltage between both ends of the selected memory cell to a predetermined voltage before select transistors are turned on. Nonvolatile memory device 100 precharges a voltage between both ends of the selected memory cell before the select transistors are switched to reduce a peak current that occurs in the set program operation.

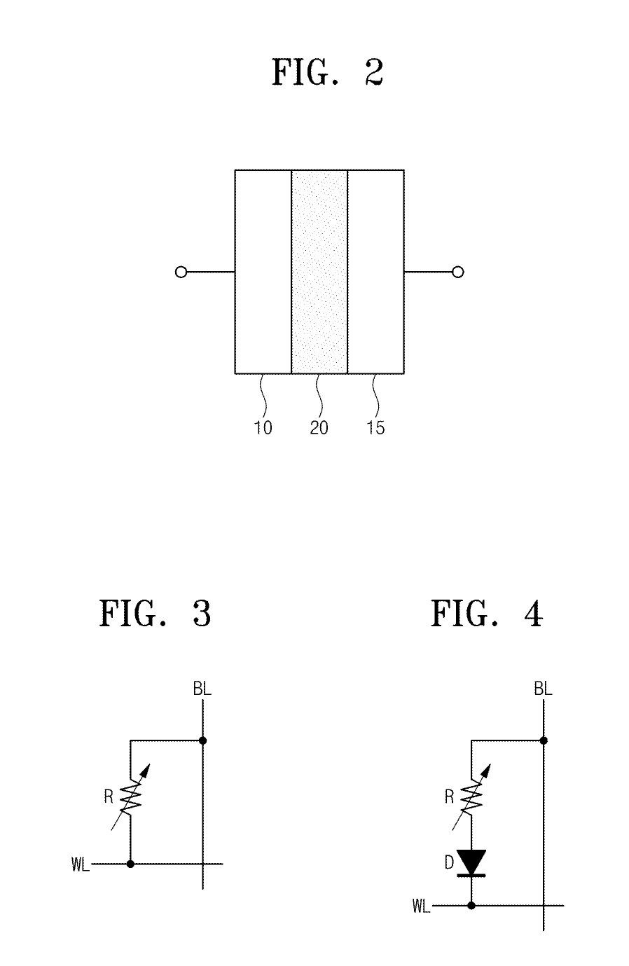

Memory cell array 110 comprises a plurality of variable resistance memory cells for storing data. The variable resistance memory cells in memory cell array 110 may take various alternative forms, such as those illustrated in FIGS. 2 and 3, for example. A program or verify voltage may be provided to a variable resistance device of the memory cell through a wordline WL or a bitline BL.

Memory cell array 110 may be formed on a two-dimensional plane, or alternatively in a three-dimensional structure. Memory cell array 110 may include wordline planes WL being stacked in a vertical direction and channels or bitlines being formed in a vertical direction. Polarity and a data storage layer may be disposed between wordline planes of each layer and a channel connected to a bitline.

Row decoder 120 decodes a row address to select any one of a plurality of wordlines connected to memory cell array 110. Row decoder 120 provides a ground voltage to a selected wordline and provides an inhibit voltage for breaking a leakage current to selected wordlines. Under control of control logic 150, row decoder 120 precharges a wordline connected to the selected memory cell to prevent occurrence of a peak current when a memory cell is programmed to a set state.

Column decoder 130 selects at least one of a plurality of bitlines connected to memory cell array 110 with reference to a column address. A bitline selected by the column select circuit 130 is connected to WD/SA 140.

WD/SA 140 programs data input to memory cell array 110 or sense data written in memory cell array 110, and outputs it under control of control logic 150.

In a program operation, WD/SA 140 provides a write voltage to a selected bitline BL. Where a memory cell is programmed from a reset state (a high resistance state) to a set state (a low resistance state), WD/SA 140 may provide various levels of limit currents Ic. Where a memory cell is programmed to the set state, WD/SA 140 may precharge a bitline connected to a selected memory cell to prevent occurrence of a peak current in response to a control of control logic 150.

Control logic 150 controls WD/SA 140, row decoder 120 and column decoder 130 in response to a write or read command being provided from the outside. Where a set program operation is performed on a selected memory cell of memory cell array 110, control logic 150 may control WD/SA 140, row decoder 120, and column decoder 130 such that a voltage between both ends of the selected memory cell is precharged to a predetermined voltage before select transistors are turned on.

Control logic 150 controls WD/SA 140, row decoder 120, and column decoder 130 such that a voltage between both ends of the selected memory cell is precharged to the same predetermined bias voltage. For example, control logic 150 may control WD/SA 140, row decoder 120 and column decoder 130 such that a local bitline and a local wordline connected to the selected memory cell are precharged to the same bias voltage.

Control logic 150 controls WD/SA 140, row decoder 120, and column decoder 130 such that a voltage between both ends of a selected memory cell is precharged to a first bias voltage and a second bias voltage, a voltage difference between the first bias voltage and the second bias voltage is less than a predetermined critical value. Control logic 150 may control WD/SA 140, row decoder 120 and column decoder 130 such that a local bitline connected to the selected memory cell is precharged to a first bias voltage and a local wordline connected to the selected memory cell is precharged to a second bias voltage.

The first and second bias voltages may be lower than a threshold voltage of a memory cell. The threshold voltage is required to change a resistance value of the memory cell.

As described above, a nonvolatile memory device may precharge a voltage level at the both ends of the selected memory cell before the selected memory cell is switched, thereby peak current occurred in a set program operation is reduced.

FIG. 2 is a drawing illustrating a structure of a variable resistance memory device.

Referring to FIG. 2, a variable resistance device comprises a pair of electrodes 10 and 15, and a data storage layer 20 disposed between electrodes 10 and 15.

Electrodes 10 and 15 may be formed of various types of metals, metal oxides or metal nitrides. Electrodes 10 and 15 may be formed of aluminum Al, copper Cu, titanium nitride TiN, titanium aluminum nitride TixAlyNz, iridium Ir, platinum Pt, silver Ag, gold Au, poly silicon, tungsten W, titanium Ti, tantalum Ta, tantalum nitride TaN, tungsten nitride WN, nickel Ni, cobalt Co, chrome Cr, antimony Sb, ferrum Fe, molybdenum Mo, palladium Pd, tin Sn, zirconium Zr, zine Zn, iridium oxide IrO2, oxide strontium zirconate StZrO3.

Data storage layer 20 may be formed of a bipolar resistance memory material or a unipolar resistance memory material. The bipolar resistance memory material may be programmed in a set or reset state by polarity of a pulse. The unipolar resistance memory material may be programmed to a set or reset state by a pulse having the same polarity. The unipolar resistance memory material may include a unipolar transition metal oxide such as NiOx or TiOx. Materials of a Perovskite structure may be used as the bipolar resistance memory material.

FIGS. 3 and 4 are circuits illustrating a memory cell structure of a variable resistance memory device. In particular, FIG. 3 illustrates a variable resistance memory cell without a select device, and FIG. 4 illustrates a variable resistance memory cell with a select device.

Referring to FIG. 3, the variable resistance memory cell comprises a variable resistance device R connected to a bitline BL and a wordline WL. In a write operation of the variable resistance memory cell of FIG. 3, data is written by a voltage being applied between a bitline BL and a wordline WL instead of the select device.

Referring to FIG. 4, the variable resistance memory cell comprises a variable resistance device R and a diode D. The select device may be embodied by a bipolar diode or a bipolar transistor besides diode D.

Variable resistance device R comprises a variable resistance material for storing data. Diode D supplies or breaks a current flowing through variable resistance device R according to a bias of wordline WL and bitline BL. Diode D is connected between variable resistance device R and wordline WL, and variable resistance device R is connected between bitline BL and diode D. Locations of diode D and variable resistance device R may be reversed. Diode D is turned on or off depending on a wordline voltage. Thus, if a voltage having a level higher than a specific level is provided to an unselected wordline WL, the variable resistance memory cell may not be driven.

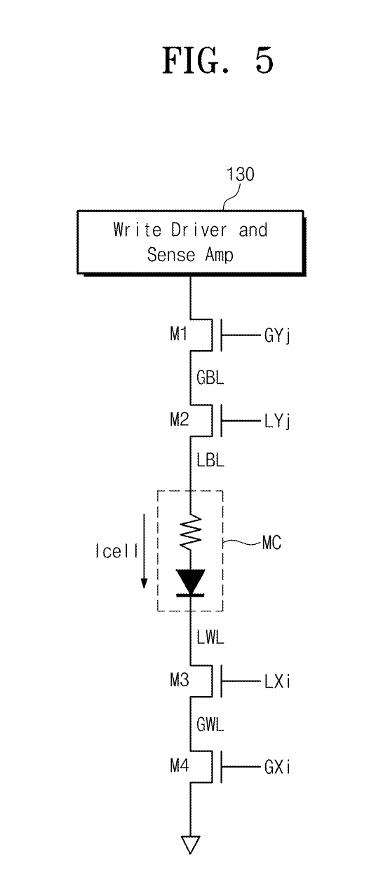

FIG. 5 is a circuit diagram illustrating an example of the memory cell of FIG. 2 connected between a bitline and a wordline. For convenience, FIG. 5 shows a bitline and a wordline corresponding to only one memory cell MC.

Referring to FIG. 5, memory cell MC is connected to a write driver and sense amplifier 130 through a local bitline LBL and a global bitline GBL. Memory cell MC is connected to a ground GND through a local wordline LWL and a global wordline GWL.

Where a voltage is applied between both ends of memory cell MC and then the voltage is increased, memory cell MC is programmed to the reset state. Where a voltage of opposite polarity is applied between both ends of memory cell MC and then the voltage is increased, memory cell MC is programmed to the set state. A set state resistance of memory cell MC is determined based on a cell current Icell flowing through memory cell MC when memory cell MC is programmed in the set state. Thus, in a program operation, the cell current Icell must be stably maintained to guarantee reliability of data programmed in memory cell MC in the set state.

A write voltage is provided to local bitline LBL connected to the selected memory cell MC to program memory cell MC in the set state. A ground voltage is provided to local wordline LWL connected to the selected memory cell MC.

To provide a write voltage to local bitline LBL, a write voltage may be provided to the global bitline GBL connected to local bitline LBL. To provide a write voltage to local bitline LBL, a first switch M1 connected between the write driver and sense amplifier 130 and the global bitline GBL and a second switch M2 connected between local bitline LBL and the global bitline GBL are turned on.

To provide a ground voltage to local wordline LWL, a ground voltage may be provided to global wordline GWL connected to local wordline LWL. To provide a ground voltage to local wordline LWL, a third switch M3 connected between local wordline LWL and global wordline GWL and a fourth switch M4 connected between global wordline GWL and ground are turned on.

First through fourth switches M1˜M4 may be implemented by transistors. For example, first through fourth switches M1˜M4 may be implemented by CMOS transistors.

While memory cell MC is programmed in the set state, memory cell MC is rapidly changed from the reset state (i.e., a high resistance state) to the set state (i.e., a low resistance state). Where a predetermined voltage is applied to memory cell MC to program it to the set state, a peak current may occur due to a current supplied from capacitors of the bitline and the wordline. In particular, because the global bitline GBL and global wordline GWL have a relatively high capacitance, in the set state program operation, a peak current that may destabilize a cell current may be supplied.

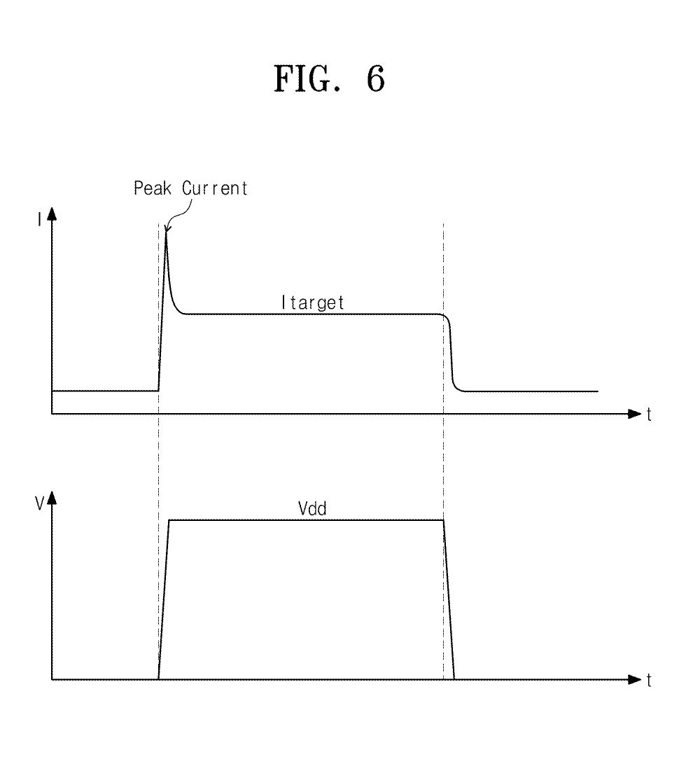

FIG. 6 is a graph illustrating a current flowing through a memory cell MC and a voltage being provided to switches connected to memory cell MC in a set state program operation. Switches connected to memory cell MC in FIG. 6 may be first through fourth switches M1˜M4 illustrated in FIG. 5.

Referring to FIGS. 5 and 6, a power supply voltage is provided to the switches, a cell current is generated in memory cell MC by a voltage difference between both ends of memory cell MC. The cell current flowing through memory cell MC is limited to a predetermined current level (Itarget). A resistance value of memory cell MC is determined based on a current level of a compliance current.

As described with reference to FIG. 5, where the switches are turned on, a peak current may occur in memory cell MC due to capacitance of the wordline and the bitline connected to memory cell MC. If the peak current occurs, data stored in memory cell MC may become unstable or endurance of memory cell MC may be degraded.

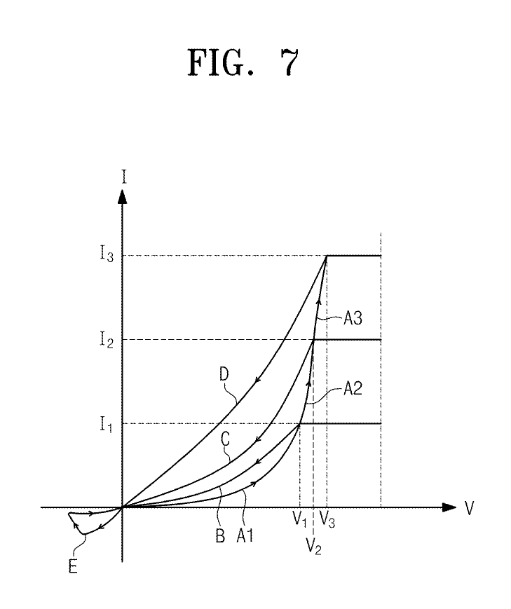

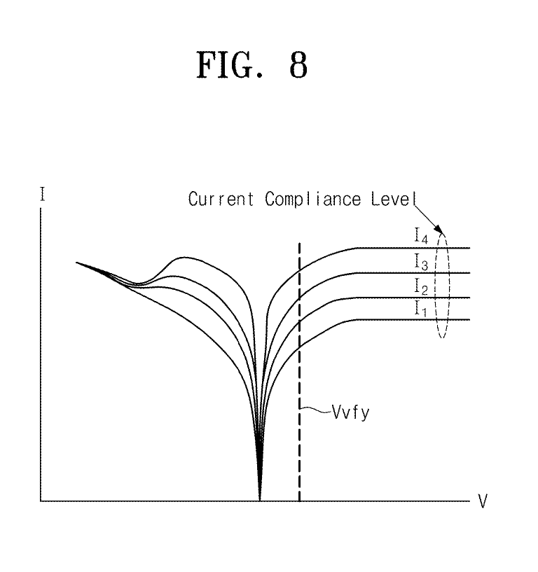

FIGS. 7 and 8 are graphs illustrating a resistance change of a memory cell according to a compliance current provided to the memory cell in a set program operation.

FIG. 7 is a graph illustrating a hysteresis characteristic of a variable resistance memory cell according to an embodiment of the inventive concept.

Referring to FIG. 7, the variable resistance memory cell exhibits different hysteresis characteristic depending on a level of compliance current. The variable resistance memory cell is written to have different set state resistances depending on a level of compliance current. The hysteresis characteristic is described with reference to a current-voltage section in which a resistance of the memory cell is changed to the reset state.

Where a voltage between both ends of the memory cell is increased in a first compliance current I₁ state, a current-voltage characteristic is represented by a curve A1. After reaching first compliance current I₁, a current of the memory cell does not increase any longer and only a voltage increases. Despite an increase of a voltage being applied between both ends of the memory cell, first compliance current I₁ is maintained constant. In this state, where the memory cell is again programmed in the set state, a voltage of opposite polarity is applied. At this time, a current-voltage characteristic is changed along a path of a curve B.

Where a voltage between both ends of the memory cell is increased in a second compliance current I₂ state, a current-voltage characteristic is represented by a curve A1-A2. After reaching the second compliance current I₂, a current of the memory cell does not increase further, and only a voltage increases. In spite of an increase of a voltage applied between both ends of the memory cell, a current flowing through the memory cell is maintained at second compliance current I₂. In this state, where the memory cell is programmed in the set state again, a voltage of opposite polarity is applied. At this time, a current-voltage characteristic is changed along a path of a curve C.

Where a voltage between both ends of the memory cell is increased in a third compliance current I₃ state, a current-voltage characteristic is represented by a curve A1-A2-A3. After reaching third compliance current I₃, a current of the memory cell does not increase further and only a voltage increases. Despite an increase of a voltage applied between both ends of the memory cell, a cell current is maintained at third compliance current I₃. In this state, where the memory cell is again programmed in the set state, a voltage of opposite polarity is applied. At this time, a current-voltage characteristic is changed along a path of a curve D. A program operation to the set state is illustrated by a curve E.

Program operations using compliance currents I₁, I₂ and I₃ are illustrated. However, where other levels of compliance currents are applied, a current-voltage characteristic of the memory cell may be represented by various hysteresis curves.

FIG. 8 is a graph illustrating a hysteresis characteristic of a variable resistance device on a Log scale. In the example of FIG. 8, compliance currents I₁, I₂, I₃ and I₄ of different levels are set to the variable resistance memory cell and then a voltage is applied.

Referring to FIG. 8, where compliance currents I₁, I₂, I₃ and I₄ of different levels are provided, because the variable resistance memory cell programmed in the set state has different set state resistances, currents of different levels flow through the variable resistance memory cell under the same verify voltage.

As described with reference to FIGS. 7 and 8, the set state resistance of memory cell MC may be determined according to a value of a cell current Icell flowing through memory cell MC when memory cell MC is programmed in the set state. Thus, to improve endurance of the memory cell and guarantee reliability of data, a peak current that occurs in a set state program operation must be reduced.

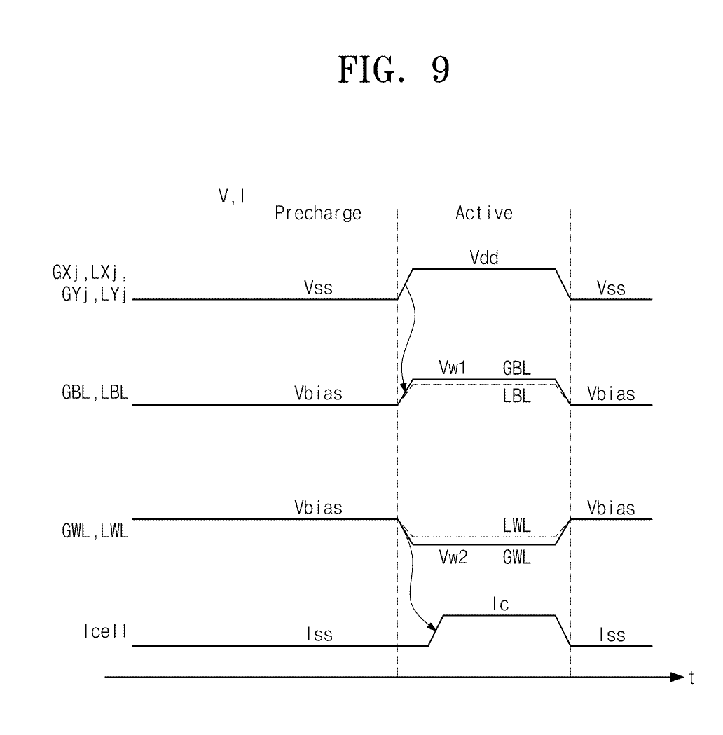

FIG. 9 is a timing diagram illustrating a method of programming nonvolatile memory device 100 of FIG. 1 according to an embodiment of the inventive concept.

Referring to FIG. 9, a wordline and a bitline that are connected to a selected memory cell are precharged to a predetermined voltage before switches connected to the memory cell are turned on. Where the switches connected to the memory cell are switched, nonvolatile memory device 100 may exhibit reduced peak current by minimizing a voltage change between both ends of memory cell MC.

During a precharge section, a global bitline select signal GYj, a local bitline select signal LYi, a global wordline select signal GXi and a local wordline select signal LXi being applied to first through fourth switches M1˜M4 (refer to FIG. 2) connected to the select memory cell may be deactivated. First through fourth switches M1˜M4 are turned in response to select signals.

During a precharge section, a global bitline GBL and a local bitline LBL are precharged to a bias voltage Vbias. Bias voltage Vbias has a level lower than a threshold voltage of the memory cell. Bias voltage Vbias may have a level half of the threshold voltage of the memory cell.

During a precharge section, a global wordline GWL and a local wordline LWL are precharged to a bias voltage Vbias. In the precharge operation, because local bitline LBL and local wordline LWL are precharged to the same voltage level, voltages of both ends of memory cell MC become equal to each other.

In an active section, global bitline select signal GYj, local bitline select signal LYi, global wordline select signal GXi and local wordline select signal LXi are activated. In response to activation of the select signals, first through fourth switches M1˜M4 are turned on. As first through fourth switches M1˜M4 are turned on, a first write voltage Vw1 from a write driver is provided to the global bitline GBL and a voltage lower than the first write voltage Vw1 by a voltage applied to the switch is provided to local bitline LBL. A second write voltage Vw2 is provided to global wordline GWL and a voltage higher than second write voltage Vw1 by a voltage applied to the switch is provided to local wordline LWL. Second write voltage Vw2 may be a ground voltage.

A voltage difference occurs between both ends of memory cell MC by a write voltage provided to local bitline LBL and local wordline LWL and a cell current Icell is generated in response to the voltage difference. By a bias voltage provided to local bitline LBL and local wordline LWL during the precharge section, the cell current Icell may be stable even when switches perform a switching operation.

In the activation section, a level of cell current Icell flowing through memory cell MC is limited to compliance current Ic. Memory cell MC is programmed in the set state under the compliance current Ic.

According to the program method described above, using a bias voltage provided from the precharge section, memory cell MC may reduce a voltage change of both ends of memory cell MC in the activation section to reduce a peak current.

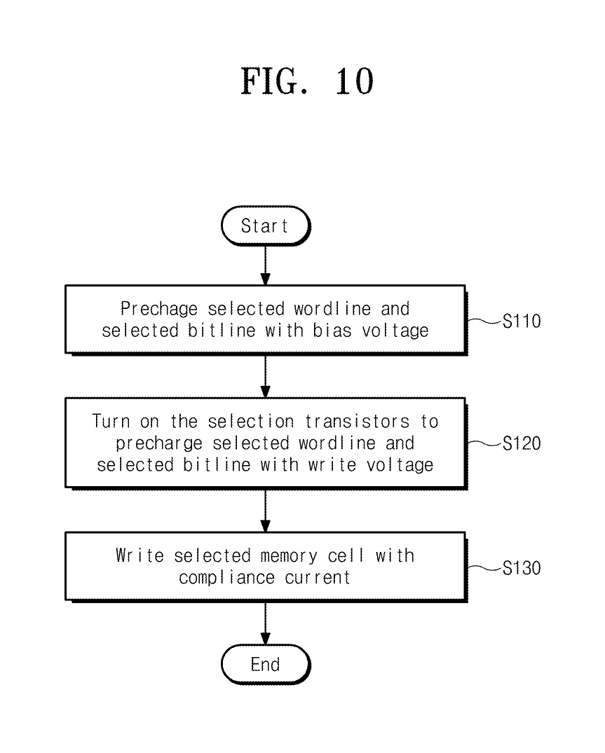

FIG. 10 is a flowchart illustrating a method of programming a nonvolatile memory device according to an embodiment of the inventive concept.

Referring to FIG. 10, in a step S110, a selected wordline and a selected bitline that are connected to a selected memory cell are precharged to a bias voltage. The selected wordline and the selected bitline may include a selected global wordline, a selected local wordline, a selected global bitline and a selected local bitline.

In a step S120, select transistors connected to the selected memory cell are turned on. The select transistors may be switches located between the selected memory cell and a write driver. A write voltage is provided to a selected wordline and a selected bitline that are connected to the selected memory cell in response to a turn-on of the select transistors.

In a step S130, the selected memory cell is programmed in the set state by a cell current generated in a memory cell by the write voltage. A level of the cell current flowing through the memory cell may be limited to the compliance current.

According to the program method described above, the nonvolatile memory device precharges both ends of the memory cell to a bias voltage in the precharge section and may reduce a voltage change of both ends of the memory cell MC during a program operation to reduce a peak current.

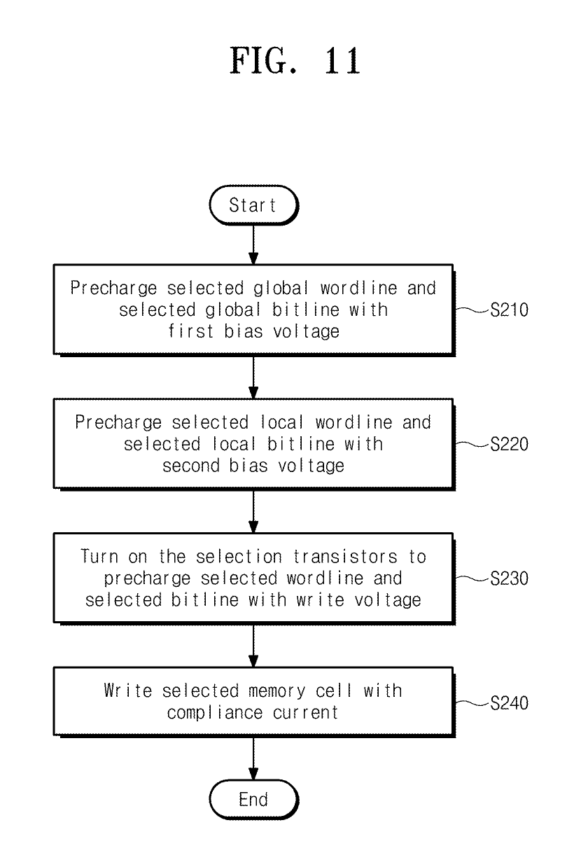

FIG. 11 is a flowchart illustrating a method of programming a nonvolatile memory device according to an embodiment of the inventive concept.

In a step S210, a selected global wordline and a selected global bitline that are connected to a selected memory cell are precharged to a first bias voltage. The first bias voltage may be lower than a threshold voltage of the memory cell. The first bias voltage may have a level half of the threshold voltage of the memory cell.

In a step S220, a selected local wordline and a selected local bitline that are connected to a selected memory cell are precharged to a second bias voltage. The second bias voltage may be lower than the first bias voltage.

In a step S230, select transistors connected to the selected memory cell are turned on. The select transistors may be switches located between the selected memory cell and a write driver. A write voltage is provided to a selected wordline and a selected bitline that are connected to the selected memory cell in response to a turn-on of the select transistors.

In a step S240, the selected memory cell is programmed in the set state by a cell current generated in a memory cell by the write voltage. A level of the cell current flowing through the memory cell may be limited to the compliance current.

According to the program method described above, the nonvolatile memory device precharges both ends of the memory cell to a bias voltage in the precharge section and may reduce a voltage change of both ends of the memory cell MC during a program operation to reduce a peak current.

In FIGS. 10 and 11, the local wordline and the local bitline are precharged to a voltage having the same level but a technical spirit of the inventive concept is not limited thereto. The local wordline and the local bitline may be precharged to different bias voltages having a voltage difference below a predetermined critical value. The predetermined critical value may be less than the threshold voltage of the memory cell.

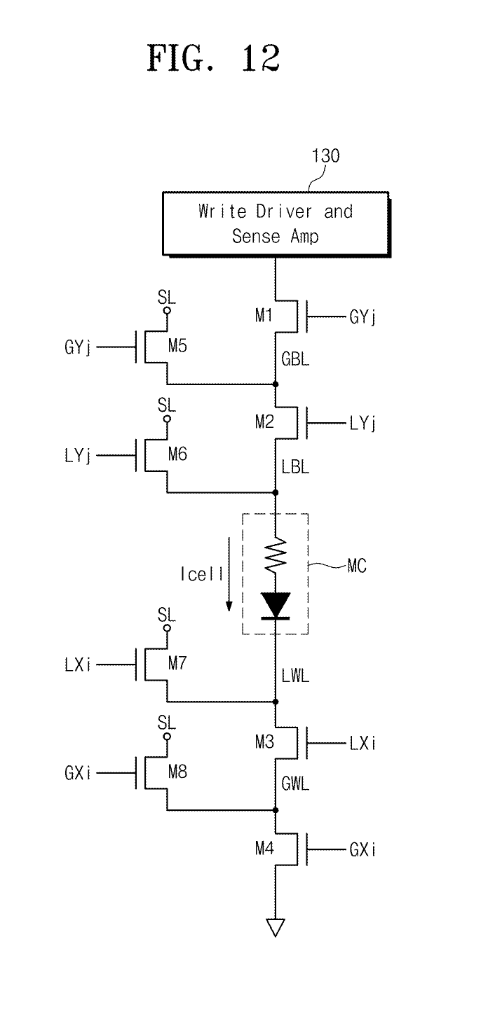

FIG. 12 is a circuit diagram illustrating another example of the memory cell of FIG. 2 connected between a bitline and a wordline. For convenience of description, in FIG. 12, a bitline and a wordline corresponding to only one memory cell MC are illustrated. Memory cell MC is connected to a write driver and sense amplifier 130 through a local bitline LBL and a global bitline GBL. Memory cell MC is connected to a ground GND through a local wordline LWL and a global wordline GWL.

Referring to FIG. 12, the nonvolatile memory device further comprises a fifth switch M5 for supplying a bias voltage to the global bitline GBL, a sixth switch M6 for supplying a bias voltage to local bitline LBL, a seventh switch M7 for supplying a bias voltage to global wordline GWL and a eighth switch M8 for supplying a bias voltage to local wordline LWL. One end of each of fifth through eighth switches M5˜M8 is connected to a selection circuit SL providing a bias voltage.

The nonvolatile memory device may provide a predetermined bias voltage to a wordline and a bitline during a precharge section using the fifth through eighth switches M5˜M8. A bias voltage being provided to each wordline and each bitline may be different from one another.

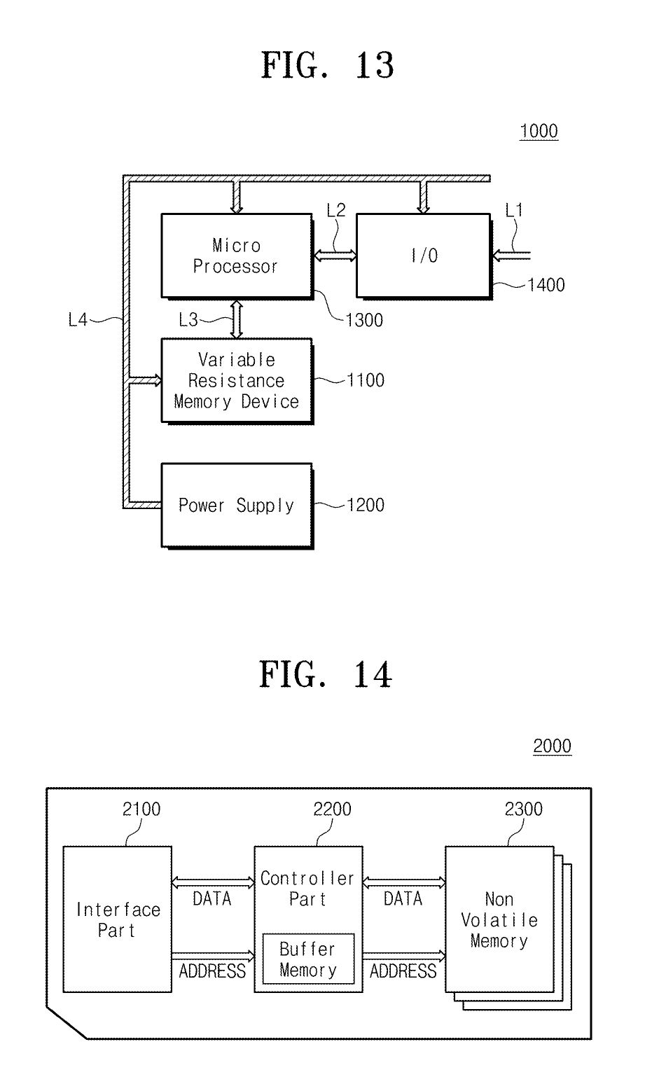

FIG. 13 is a block diagram illustrating a portable electronic system 1000 comprising a variable resistance memory device 1100 according to an embodiment of the inventive concept.

Referring to FIG. 13, variable resistance memory device 1100 precharges both ends of the memory cell to a bias voltage in a precharge section and may reduce a voltage change of both ends of memory cell MC during a program operation to reduce a peak current.

Resistive memory device 1100 is connected to a microprocessor 1300 through a bus line L3 and is provided as a main memory of a portable electronic system. A power supply unit 1200 supplies power to microprocessor 1300, an input/output device 1400 and the phase change memory device 1100 through a power supply line L4. Microprocessor 1300 and input/output device 1400 may be provided as a memory controller for controlling resistive memory device 1100.

Where received data is provided to input/output device 1400 through a line L1, microprocessor 1300 receives the received data through a line L2, processes the received data, and then applies the processed data to resistive memory device 1100 through the bus line L3. Resistive memory device 1100 stores data being applied through bus line L3 in a memory cell. Data stored in the memory cell is read by microprocessor 1300 and then is output to the outside through the input/output device 1400.

Even where power of power supply unit 1200 is not supplied to the power supply line L4, data stored in the memory cell of resistive memory device 1100 is not lost because resistive memory device 1100 is a nonvolatile memory. Resistive memory device 1100 also has potential benefits of relatively high operational speed and relatively low power consumption.

FIG. 14 is a block diagram illustrating a memory card 2000 comprising a nonvolatile memory device according to an embodiment of the inventive concept. Memory card 2000 may be, for example, a MMC card, a SD card, a multiuse card, a micro SD card, a memory stick, a compact SD card, an ID card, a PCMCIA card, a SSD card, a chipcard, a smart card, a USB card, etc.

Referring to FIG. 14, memory card 2000 comprises an interface part 2100 performing an interface with the outside, a controller 2200 comprising a buffer memory and controlling an operation of the memory card 200 and at least one of nonvolatile memory devices 2300. Controller 2200 controls read and write operations of nonvolatile memory device 2300. Controller 2200 is coupled to nonvolatile memory device 2300 and interface part 2100 through a data bus DATA and an address bus ADDRESS.

Nonvolatile memory device 2300 precharges both ends of the memory cell to a bias voltage in a precharge section and may reduce a voltage change of both ends of memory cell MC during a program operation to reduce a peak current.

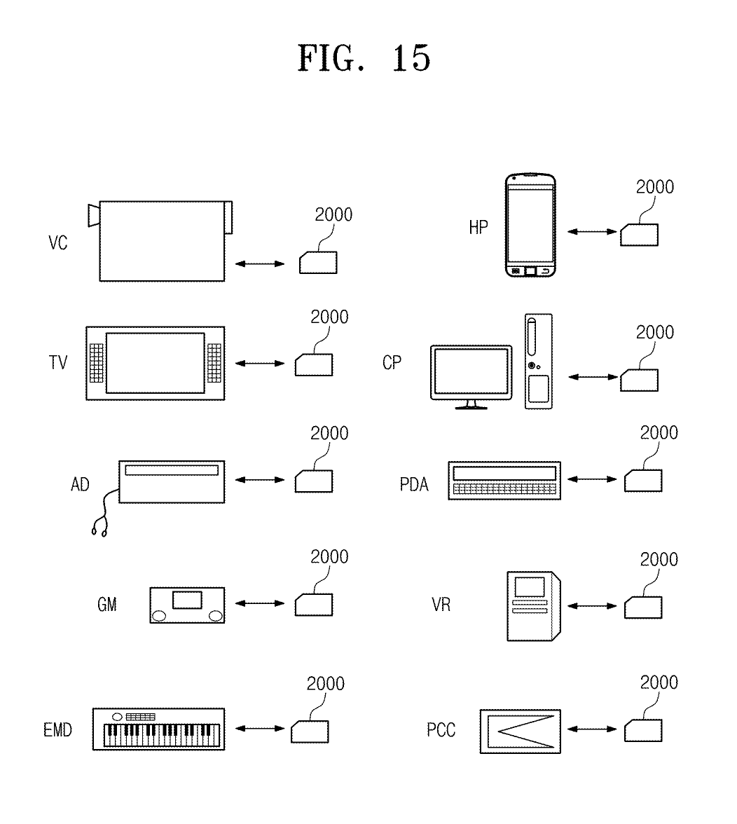

FIG. 15 is a drawing illustrating various systems in which a memory card of FIG. 14 is used.

Referring to FIG. 15, a memory card 2000 may be used in (a) a video camera, (b) a television, (c) an audio device, (d), a game device, (e) an electronic music device, (f) a cellular phone, (g) a computer, (h) a PDA (personal digital assistant), (i) a voice recorder, (j) a X PC card, etc.

Nonvolatile memory devices as described above may be packages using any of various types of packages or package configurations, such as package on package (PoP), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), system in package (SIP), multi chip package (MCP), wafer-level fabricated package (WFP) and wafer-level processed stack package (WSP).

As indicated by the foregoing, in some embodiments of the inventive concept, a nonvolatile memory device and related method may provide reduced peak current in a set program operation. The reduction of the peak current can improve the endurance of the nonvolatile memory device.

The foregoing is illustrative of embodiments and is not to be construed as limiting thereof. Although a few embodiments have been described, those skilled in the art will readily appreciate that many modifications are possible in the embodiments without materially departing from the scope of the inventive concept. Accordingly, all such modifications are intended to be included within the scope of the inventive concept as defined in the claims.

What is claimed is:

1. A method of programming a nonvolatile memory device comprising a variable resistance memory cell connected to a bitline and a wordline, the method comprising:
precharging the bitline to a first bias voltage;
precharging the wordline to a second bias voltage, wherein a voltage difference between the first bias voltage and the second bias voltage is less than a threshold voltage of the memory cell; and
applying a first write voltage to the bitline and a second write voltage to the wordline in response to a select signal, wherein a voltage difference between the first write voltage and the second write voltage is greater than the threshold voltage.

2. The method claim 1, wherein the first bias voltage has the same level as the second bias voltage.

3. The method of claim 1, wherein the first bias voltage has a value between the threshold voltage and a ground voltage.

4. The method of claim 1, wherein the second write voltage is a ground voltage.

5. The method of claim 1, wherein the bitline comprises a local bitline connected to the memory cell and a global bitline connected between the local bitline and a write driver, and wherein precharging the bitline to the first bias voltage comprises precharging the local bitline to the first bias voltage.

6. The method of claim 5, wherein the wordline comprises a local wordline connected to the memory cell and a global wordline connected between the local wordline and a ground, and wherein precharging the wordline to a second bias voltage comprises precharging the local wordline to the second bias voltage.

7. A nonvolatile memory device, comprising:
a memory cell array comprising a memory cell in which data is stored by changing the memory cell's resistance value;
an input/output driver connected to the memory cell array through a first switch group connected to a plurality of wordlines and a second switch group connected to a plurality of bitlines; and
control logic configured to control the input/output driver such that, in a program operation, a selected wordline and a selected bitline that are connected to a selected memory cell are precharged to a predetermined bias voltage before switches in the first and second switch groups are activated.

8. The nonvolatile memory device of claim 7, wherein the control logic controls the input/output driver such that the selected wordline and the selected bitline are precharged to the same bias voltage.

9. The nonvolatile memory device of claim 8, wherein the bias voltage has a level less than a threshold voltage of the selected memory cell.

10. The nonvolatile memory device of claim 7, wherein the control logic controls the input/output driver such that the selected bitline is precharged to a first bias voltage and the selected wordline is precharged to a second bias voltage less than the first bias voltage.

11. The nonvolatile memory device of claim 10, wherein a voltage difference between the first bias voltage and the second bias voltage is less than a threshold voltage of the memory cell.

12. The nonvolatile memory device of claim 7, wherein switches in the first and second switch groups comprise complementary metal oxide semiconductor (CMOS) transistors.

13. The nonvolatile memory device of claim 7, wherein the input/output driver comprises a third switch group connected to the wordlines and a fourth switch group connected to the bitlines, and
wherein the third switch group is complementarily activated with the first switch group and the fourth switch group is complementarily activated with the second switch group.

14. The nonvolatile memory device of claim 7, wherein the control logic controls the input/output driver such that a first write voltage is provided to the selected bitline and a second write voltage is provided to the selected wordline after the selected wordline and the selected bitline are precharged to the bias voltage.

15. The nonvolatile memory device of claim 14, wherein the second write voltage is a ground voltage.

16. A method of programming a nonvolatile memory device comprising a variable resistance memory cell connected to a global wordline, a global bitline, a local wordline, and a local bitline, the method comprising:
precharging the global wordline and the global bitline to a first bias voltage that is lower than a threshold voltage of the memory cell;
precharging the local wordline and the local bitline to a second bias voltage that is lower than the first bias voltage;
turning on select transistors connected to the memory cell; and
applying a write voltage to the memory cell via the local wordline, the local bitline, and the select transistors.

17. The method of claim 16, wherein the first bias voltage has a level that is half of the threshold voltage of the memory cell.

18. The method of claim 16, wherein the select transistors are disposed between the memory cell and a write driver.

19. The method of claim 16, wherein the memory cell is programmed to a set state by a cell current generated by the write voltage.

20. The method of claim 19, wherein the cell current is limited to a level of a compliance current.
